(19) United States
(12) Patent Application Publication
(10) Pub. No.: US 2008/0067685 A1
(43) Pub. Date: Mar. 20, 2008

(54) Semiconductor Device Manufacturing Method

(75) Inventor: Byung Soo Eun, Seoul (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-si (KR)

(21) Appl. No.: 11/761,592

(22) Filed: Jun. 12, 2007

(30) Foreign Application Priority Data
Sep. 19, 2006 (KR) 10-2006-0090848

(51) Int. Cl. H01L 23/52; H01L 21/44

(52) U.S. Cl. 257/773; 438/597; 257/E23.141; 257/E21.476

(57) ABSTRACT

A semiconductor device manufacturing method includes forming a conductive layer pattern on a semiconductor substrate, forming a seed layer having a high silicon content ratio on the conductive layer pattern, and forming an interlayer dielectric to bury the conductive layer pattern on the seed layer.

### CROSS-REFERENCES TO RELATED APPLICATIONS

The present application claims priority to Korean patent application number 10-2006-90848, filed on Sep. 19, 2006, which is incorporated by reference in its entirety.

### BACKGROUND OF THE INVENTION

The present invention relates to a semiconductor device, and, more particularly, to a semiconductor device manufacturing method that is capable of stabilizing the threshold voltage of a device.

The recent high-integration of a semiconductor device has reduced a design rule of the device. As a result, the size of the semiconductor device has further decreased. The reduction in size of the device requires more rapid speed of the device, resulting in the further decrease in thickness of a gate oxide.

With the decrease in thickness of the gate oxide, the gate oxide may be exposed and deteriorated at several processes of a semiconductor device manufacturing method. As the processes of the semiconductor device manufacturing method are repeatedly performed, the gate oxide may be easily broken by bias applied to the gate oxide. For example, the breakage of the gate oxide may occur at a process of forming a high density plasma oxide with an interlayer dielectric.

For a conventional dynamic random access memory (DRAM) device, conductive layers, e.g., bit lines, are formed by a chemical vapor deposition using tungsten W. The insulation between the conductive layers is accomplished by using a high density plasma oxide as a dielectric. In the high density plasma oxide, however, a high density plasma is used with the result that a large number of hydrogen (H₂) ions and charges penetrate into the gate oxide through the conductive layers, e.g., the bit lines, during deposition, and accumulate in the gate oxide. The penetration and accumulation of the hydrogen (H₂) ions and charges in the gate oxide changes the threshold voltage of the device. Also, high bias is applied to the gate oxide with the result that cracks occur in the gate oxide, thereby deteriorating the reliability of the device.

### SUMMARY OF THE INVENTION

One embodiment of the present relates to a semiconductor device manufacturing method is capable of forming a passivation film at a process of forming an interlayer dielectric, thereby preventing the defectiveness of a gate oxide.

For example, a semiconductor device manufacturing method may include forming a conductive layer pattern over a semiconductor substrate, forming a seed layer having a high silicon content ratio on the conductive layer pattern, and forming an interlayer dielectric to bury the conductive layer pattern on the seed layer.

Preferably, forming the seed layer includes loading the semiconductor substrate in a high density plasma chamber, supplying a source gas, including a silane (SiH₄) gas and an oxygen (O₂) gas, and a carrier gas, including a helium (He) gas, into the high density plasma chamber and applying power to the high density plasma chamber to generate plasma, and adsorbing the plasma material onto the semiconductor substrate.

Preferably, the silane (SiH₄) gas and the oxygen (O₂) gas are supplied in a ratio of 1:1 to 1.1.

Preferably, generating the plasma includes supplying the silane (SiH₄) gas at a flow rate of 30 to 40 sccm, the oxygen (O₂) gas at a flow rate of 30 to 45 sccm, and the (He) gas at a flow rate of 800 to 1000 sccm, applying a power of 2000 to 4000 W at a low frequency, and applying a power of 600 to 800 W at a high frequency.

Preferably, the seed layer is formed such that the thickness of the seed layer does not exceed 300 Å.

Preferably, forming the seed layer includes supplying a helium gas to the backside of the semiconductor substrate.

Preferably, forming the seed layer and the step of forming the interlayer dielectric are performed in an in-situ fashion.

Another embodiment provides a semiconductor device manufacturing method may include forming a bit line stack over a semiconductor substrate, forming a spacer film on the side wall of the bit line stack, forming a seed layer having a high silicon content ratio on the bit line stack, supplying a helium gas to the backside of the semiconductor substrate while forming the seed layer, and forming an interlayer dielectric to bury the bit line stack on the seed layer.

Preferably, forming the seed layer includes loading the semiconductor substrate in a high density plasma chamber, supplying a source gas, including a silane (SiH₄) gas and an oxygen (O₂) gas, and a carrier gas, including a helium (He) gas, into the high density plasma chamber and applying power to the high density plasma chamber to generate plasma, and adsorbing the plasma material onto the semiconductor substrate.

Preferably, the silane (SiH₄) gas and the oxygen (O₂) gas are supplied in a ratio of 1:1 to 1.1.

Preferably, the seed layer is formed such that the thickness of the seed layer does not exceed 300 Å.

Preferably, forming the seed layer and the step of forming the interlayer dielectric are performed in an in-situ fashion.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a view illustrating voids created in an interlayer dielectric; and

FIGS. 2 to 6 are views illustrating a semiconductor device manufacturing method according to an embodiment of the present invention.

### DETAILED DESCRIPTION

Embodiments of the present invention will now be described in detail with reference to the accompanying drawings. It should be noted, however, that the present invention may be embodied in various different forms, and therefore, the present invention is not limited to the illustrated embodiments. The thicknesses of components shown in the drawings may be exaggerated for simplicity and clarity of description. In the drawings, the same or similar elements are denoted by the same reference numerals even though they are depicted in different drawings.

During the deposition of an interlayer dielectric to bury various patterns, e.g., a conductive layer pattern, formed on a DRAM device, a large number of hydrogen ions and charges are generated, penetrate into a gate oxide through the conductive layer pattern, and accumulate in the gate oxide. The penetration and accumulation of the hydrogen ions and charges in the gate oxide changes the threshold voltage of the device. Also, high bias is applied to the gate oxide with the result that cracks occur in the gate oxide, thereby deteriorating the reliability of the semiconductor device.

In order to prevent the penetration of the hydrogen ions and charges into the conductive layer pattern, there has been proposed a method of depositing an interlayer dielectric at a low temperature sufficient to cool the backside of a semiconductor substrate. In this method, the low temperature decreases the moving speed of the charges, thereby improving gate oxide integrity (GOI) to some extent. When the interlayer dielectric is deposited at the low temperature, however, the gap-fill characteristics may be deteriorated. The deterioration of the gap-fill characteristics to bury the conductive layer pattern may create defects, such as voids, in the interlayer dielectric.

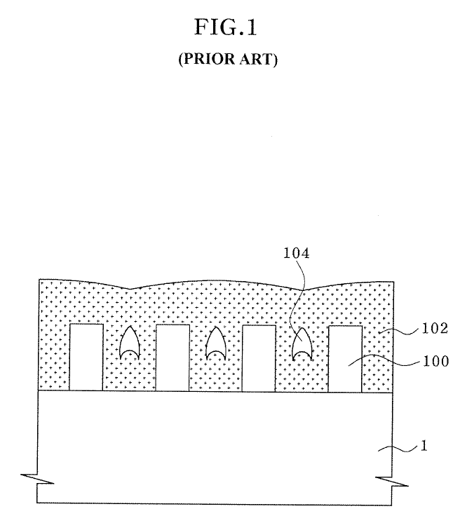

FIG. 1 is a view illustrating voids created in an interlayer dielectric.

When depositing an interlayer dielectric 102 at a low temperature sufficient to cool the backside of a semiconductor substrate in order to prevent the penetration of hydrogen ions and charges into conductive layer pattern 100, the gap-fill characteristics are deteriorated with the result that the interlayer dielectric 102 is not completely buried, and therefore, voids 104 are created in the interlayer dielectric 102. When the voids 104 are created in the interlayer dielectric 102, a landing plug bridge phenomenon may occur at a subsequent process of forming landing plugs, which adversely affects the yield rate. Furthermore, when the interlayer dielectric 102 is deposited at the low temperature, it is required to continuously expose a wafer or a semiconductor substrate to a highly-charged plasma at a subsequent plasma process, which deteriorates the reliability of a gate oxide.

In order to prevent the occurrence of the void defects, the interlayer dielectric may be deposited at a low deposition rate. In this case, however, the throughput decreases, and the investment of a related apparatus is required. Consequently, the method of depositing the interlayer dielectric at the low deposition rate is not efficient. Furthermore, these problems may be further serious when the thickness of the gate oxide further decreases and the number of processes increases.

In a specific embodiment of the present invention, a bit line stack will be described as an example; however, it is obvious that the interlayer dielectric forming method according to the present invention is also used for a gate stack.

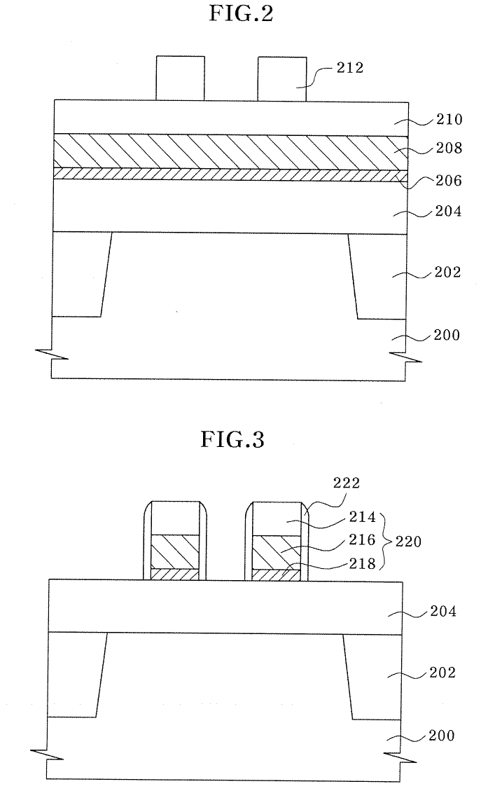

FIGS. 2 to 6 are views illustrating a semiconductor device manufacturing method according to an embodiment of the present invention.

Referring first to FIG. 1, a first interlayer dielectric 204 is formed on a semiconductor substrate 200 whose active region is defined by a trench device isolation layer 202. Although not shown in the drawing, a word line, including a gate insulation layer, is formed over the first interlayer dielectric 204. The first interlayer dielectric 204 may be formed including a high density plasma oxide. At this time, the first interlayer dielectric 204 may include a contact plug (not shown) connected to the semiconductor substrate 200.

Subsequently, a barrier metal layer 206, a bit line conductive layer 208, and a hard mask layer 210 are sequentially formed on the first interlayer dielectric 204. The barrier metal layer 206 may be formed of a titanium (Ti)/titanium nitride (TiN) film, and the bit line conductive layer 208 may be formed of a tungsten (W) film. At this time, the titanium nitride (TiN) film may serve to prevent the titanium (Ti) film from reacting with a source material when depositing the bit line conductive layer 208, e.g., the tungsten (W) film. Alternatively, the titanium nitride (TiN) film may serve as a glue layer to assist easy growth of the bit line conductive layer 208.

The hard mask layer 210 may be formed of a nitride film. However, the hard mask layer 210 is not limited to the nitride film, and therefore, the hard mask layer 210 may be formed of another similar film. Subsequently, a photoresist film is applied and patterned on the hard mask layer 210 to form a photoresist pattern 212 defining a bit line stack forming region.

Referring to FIG. 3, an etching process is performed using the photoresist pattern 212 as a mask to form a bit line stack 220 on the semiconductor substrate 200 and the first interlayer dielectric 204. The bit line stack 220 includes a hard mask pattern 214, a bit line conductive layer pattern 216, and a barrier metal pattern 218 which are sequentially stacked. Subsequently, a spacer nitride film (not shown) is formed on the bit line stack 220 and the first interlayer dielectric 204. The spacer nitride film is etched to form a bit line spacer film 222 on the side wall of the bit line stack 220.

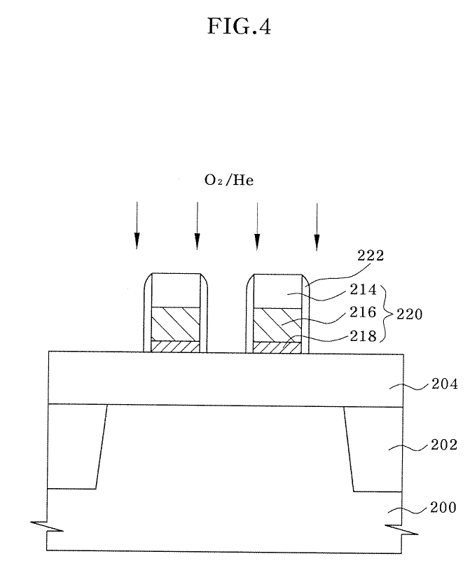

Referring to FIG. 4, the semiconductor substrate 200 is preheated at a gas atmosphere including helium (He) and oxygen (O₂) to relax the semiconductor substrate 200.

Specifically, the semiconductor substrate 200 is loaded into a high density plasma chamber. After that, appropriate voltage is applied to the high density plasma chamber, while an oxygen (O₂) gas, as a source gas, and a helium (He) gas, as an additive gas, are supplied into the high density plasma chamber, to preheat the semiconductor substrate 200 for 40 seconds to 60 seconds. The oxygen (O₂) gas is supplied at a flow rate of 400 sccm to 600 sccm, and the helium (he) gas is supplied at a flow rate of 300 sccm to 450 sccm. Also, a source power of 2000 W to 4000 W is applied at a low frequency to generate plasma. The preheating process further increases the relaxation of the semiconductor substrate 200 to reduce the stress applied to the semiconductor substrate 200. At this time, helium may be supplied to cool the backside of the semiconductor substrate or a wafer.

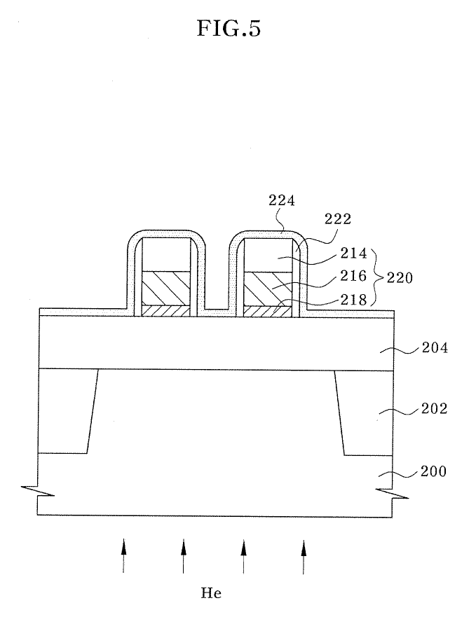

Referring to FIG. 5, a seed layer 224 is formed on the bit line stack 220 to prevent penetration of ions and charges into the bit line conductive layer pattern.

Specifically, a source gas, including a silane (SiH₄) gas and an oxygen (O₂) gas, and a carrier gas, including a helium (He) gas, are supplied into the high density plasma chamber, in which the preheated bit line stack 220 is placed. Subsequently, power is applied to the high density plasma chamber such that plasma is generated in the high density plasma chamber, and bias power is applied to form a seed layer 224 on the bit line stack 220. The seed layer 224 may be formed by supplying the silane (SiH₄) gas at a flow rate of 30 sccm to 45 sccm, the oxygen (O₂) gas at a flow rate of 33 sccm to 48 sccm, and the (He) gas at a flow rate of 800 sccm to 1000 sccm. Subsequently, a power of 2000 W to 4000 W is applied at a low frequency to generate plasma, and a power of 600 W to 800 W is applied at a high frequency to adsorb a plasma-phase material onto the bit line stack 220. In a specific embodiment of the present invention, the silane (SiH₄) gas is supplied at a flow rate of 35 seem, the oxygen (O₂) gas is supplied at a flow rate of 38 sccm, and the (He) gas is supplied at a flow rate of 900 sccm. After that, a power of 3000 W is applied at a low frequency to generate plasma, and then a power of 700 W is applied at a high frequency to adsorb a plasma-phase material onto the bit line stack 220. As a result, the seed layer 224 is formed such that the seed layer has a thickness of 200 Å to 400 Å.

At this time, it is preferable to supply a helium gas to the backside of the wafer or the semiconductor substrate 200 such that the backside of the wafer or the semiconductor substrate 200 is cooled to prevent the damage to the device due to the plasma during the plasma process.

When depositing the high density plasma oxide using the interlayer dielectric, on the other hand, the silane (SiH₄) gas and the oxygen (O₂) gas are supplied in a ratio of 1.38 in a conventional art. For example, the oxygen (O₂) gas is supplied at a flow rate of 48 seem when the silane gas is supplied at a flow rate of 35 sccm. In a specific embodiment of the present invention, however, the oxygen (O₂) gas is supplied at a low flow rate of 38 seem to form the seed layer 224 having a high silicon (Si) content ratio in the high density plasma oxide. Preferably, the seed layer 224 is formed such that the seed layer 224 has a thickness of 200 Å to 400 Å. When the seed layer 224 is too thick, the insulation efficiency of the conductive layer pattern is lowered, and parasitic capacitance charge amount is increased due to high dielectric constant of the high density plasma oxide having a high silicon (Si) content ratio with the result that the speed of the device is adversely affected. Consequently, it is preferable to form the seed layer 224 such that the thickness of the seed layer 224 does not exceed 300 Å.

When an interlayer dielectric is subsequently formed to bury the bit line stack 220, the silicon (Si) contained in the seed layer 224 having a high silicon (Si) content ratio serves to traps hydrogen (H) ions and charge particles generated when using the plasma, thereby preventing the movement of the hydrogen (H) ions and charge particles to the gate oxide side.

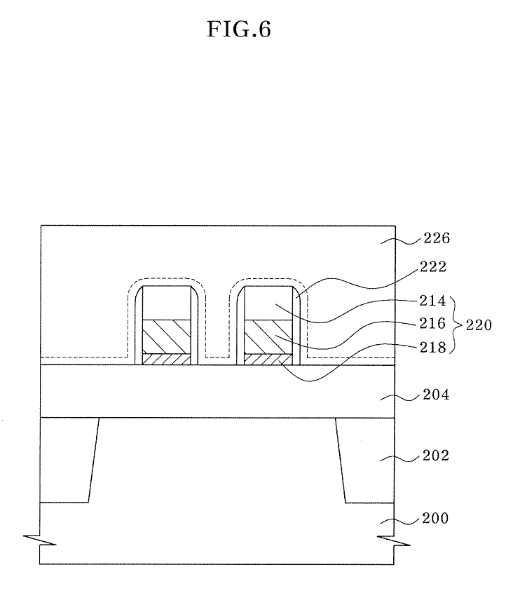

Referring to FIG. 6, a second interlayer dielectric 226 is formed to bury the bit line stack 220.

Specifically, a silane (SiH₄) gas and an oxygen (O₂) gas are additionally supplied into the high density plasma chamber to form a high density plasma oxide having a thickness of 2500 Å to 3500 Å. The silane (SiH₄) gas is supplied at a flow rate of 40 sccm to 60 sccm, and the oxygen (O₂) gas is supplied at a flow rate of 60 sccm to 75 sccm. The backside of the wafer or the semiconductor substrate 200 is not cooled but is maintained at a high temperature to prevent the deterioration of the gap-fill characteristics. In a conventional art, the gate oxide may be deteriorated during a high-temperature plasma process. According to an embodiment of the present invention, however, the seed layer is formed on the bit line stack 220 after forming the bit line stack 220. As a result, the seed layer having a high silicon content ratio serves a barrier to the hydrogen ions and charge particles. Consequently, it is possible to perform the high density plasma process at a temperature higher than that of the conventional art, thereby improving the gap-fill characteristics. Also, it is possible to increase the amount of silane gas supplied, thereby increasing the throughput.

Subsequently, a silane (SiH₄) gas and an oxygen (O₂) gas are further supplied into the high density plasma chamber to form a second interlayer dielectric having a thickness of 2000 Å to 2500 Å on the high density plasma oxide. The silane (SiH₄) gas is supplied at a flow rate of 100 sccm to 250 sccm, and the oxygen (O₂) gas is supplied at a flow rate of 200 sccm to 355 sccm. After that, a helium (He) gas is supplied at a flow rate of 400 sccm to 600 sccm. Subsequently, a power of 3000 W to 5000 W is applied at a low frequency to generate plasma, and a power of 1000 W to 20000 W is applied at a high frequency to adsorb a plasma-phase material onto the bit line stack 220, thereby forming a second interlayer dielectric 226.

The preheating process or the second interlayer dielectric forming process may be performed in the high density plasma chamber in an in-situ fashion.

In an embodiment of the semiconductor device forming method according to the present invention, the seed layer having the high silicon content ratio is formed on the bit line stack as the barrier layer. As a result, the silicon contained in the seed layer serves to trap hydrogen ions and charge particles generated during the manufacture of the semiconductor device. Consequently, it is possible to prevent the defectiveness of the gate oxide and to form the interlayer dielectric at a high temperature, thereby improving the reliability of the device.

As apparent from the above description, the seed layer having the high silicon content ratio is formed on the conductive layer pattern as the barrier layer. Consequently, the semiconductor device forming method according to an embodiment of the present invention has the effect of preventing the hydrogen ions and charge particles generated during the high density plasma process from penetrating into the gate oxide through the conductive layer pattern and thus deteriorating the gate oxide. As a result, it is possible to perform the process for burying the conductive layer pattern with the high density plasma oxide at high temperature. Also, it is possible to increase the amount of silane gas supplied, thereby increasing the throughput. Furthermore, the reliability of the gate oxide of the device is improved.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A semiconductor device manufacturing method comprising:
forming a conductive layer pattern over a semiconductor substrate;
forming a seed layer having a high silicon content ratio on the conductive layer pattern; and
forming an interlayer dielectric to bury the conductive layer pattern on the seed layer.

2. The semiconductor device manufacturing method according to claim 1, wherein forming the seed layer includes
loading the semiconductor substrate in a high density plasma chamber,
supplying a source gas, including a silane (SiH₄) gas and an oxygen (O₂) gas, and a carrier gas, including a helium (He) gas, into the high density plasma chamber and applying power to the high density plasma chamber to generate plasma, and
adsorbing the plasma material onto the semiconductor substrate.

3. The semiconductor device manufacturing method according to claim 2, wherein the silane (SiH₄) gas and the oxygen (O₂) gas are supplied in a ratio of 1:1 to 1.1.

4. The semiconductor device manufacturing method according to claim 2, wherein generating the plasma includes
supplying the silane (SiH₄) gas at a flow rate of 30 sccm to 40 sccm, the oxygen (O₂) gas at a flow rate of 30 sccm to 45 sccm, and the (He) gas at a flow rate of 800 sccm to 1000 sccm, applying a power of 2000 W to 4000 W at a low frequency, and applying a power of 600 W to 800 W at a high frequency.

5. The semiconductor device manufacturing method according to claim 1, wherein the seed layer is formed such that the thickness of the seed layer does not exceed 300 Å.

6. The semiconductor device manufacturing method according to claim 1, wherein forming the seed layer includes
supplying a helium gas to the backside of the semiconductor substrate.

7. The semiconductor device manufacturing method according to claim 1, wherein forming the seed layer and the step of forming the interlayer dielectric are performed in an in-situ fashion.

8. A semiconductor device manufacturing method comprising:
forming a bit line stack over a semiconductor substrate;
forming a spacer film on the side wall of the bit line stack;
forming a seed layer having a high silicon content ratio on the bit line stack;
supplying a helium gas to the backside of the semiconductor substrate while forming the seed layer; and
forming an interlayer dielectric to bury the bit line stack on the seed layer.

9. The semiconductor device manufacturing method according to claim 8, wherein forming the seed layer includes
loading the semiconductor substrate in a high density plasma chamber,
supplying a source gas, including a silane (SiH₄) gas and an oxygen (O₂) gas, and a carrier gas, including a helium (He) gas, into the high density plasma chamber and applying power to the high density plasma chamber to generate plasma, and
adsorbing the plasma material onto the semiconductor substrate.

10. The semiconductor device manufacturing method according to claim 9, wherein the silane (SiH₄) gas and the oxygen (O₂) gas are supplied in a ratio of 1:1 to 1.1.

11. The semiconductor device manufacturing method according to claim 9, wherein the seed layer is formed such that the thickness of the seed layer does not exceed 300 Å.

12. The semiconductor device manufacturing method according to claim 9, wherein forming the seed layer and the step of forming the interlayer dielectric are performed in an in-situ fashion.

13. A semiconductor device comprising:
a semiconductor substrate;
a first interlayer dielectric formed on the semiconductor substrate;
a bit line stack formed over the first interlayer dielectric;
a seed layer, having a high silicon content ratio, formed over the bit line stack; and
a second interlayer dielectric formed to bury the seed layer and the bit line stack.

14. The semiconductor device according to claim 13, wherein the seed layer has a thickness not more than 300 Å.
